(19) United States
(12) Patent Application Publication
(10) Pub. No.: US 2019/0368638 A1
(43) Pub. Date: Dec. 5, 2019

(54) SILICA NANOFIBER MATERIALS, ARTICLES INCLUDING SUCH MATERIALS, AND RELATED METHODS

(71) Applicant: Battelle Energy Alliance, LLC, Idaho Falls, ID (US)

(72) Inventors: Jesse L. Reeves, Ammon, ID (US); Bjorn C. Vaagensmith, Idaho Falls, ID (US)

(21) Appl. No.: 16/430,478

(22) Filed: Jun. 4, 2019

Related U.S. Application Data
(60) Provisional application No. 62/680,179, filed on Jun. 4, 2018.

(51) Int. Cl. F16L 9/10; D01F 9/08; D01D 5/00; H01F 27/28; H01B 3/08; H01B 7/02; H01L 23/29

(52) U.S. Cl. CPC F16L 9/105; D01F 9/08; D01D 5/003; D10B 2101/06; H01B 3/084; H01B 7/0241; H01L 23/291; H01F 27/2823

(57) ABSTRACT

A silica nanofiber material includes a flexible mat comprising a plurality of silica nanofibers. An electrical device may include an electrical component and the silica nanofiber material disposed over the electrical component. A method of forming a silica nanofiber material includes electrospinning a fluid comprising a silica precursor and a polymer to form electrospun fibers, removing at least a portion of the polymer from the electrospun fibers to form silica nanofibers, and annealing the silica nanofibers to bind the silica nanofibers together.

### CROSS-REFERENCE TO RELATED APPLICATION

This application claims the benefit, under 35 U.S.C. § 119(e), of U.S. Provisional Patent Application Ser. No. 62/680,179, filed Jun. 4, 2018, the disclosure of which is hereby incorporated herein in its entirety by this reference.

### STATEMENT REGARDING FEDERALLY SPONSORED RESEARCH OR DEVELOPMENT

This invention was made with government support under Contract Number DE-AC07-05-ID14517 awarded by the United States Department of Energy. The government has certain rights in the invention.

### TECHNICAL FIELD

Embodiments of the present disclosure relate generally to materials for electrical insulation, thermal insulation, corrosion resistance, and/or filtration; to articles (e.g., devices (e.g., electrical devices), components (e.g., electrical components), industrial articles (e.g., piping, filters)) that include such materials; and to methods of forming such materials. More particularly, embodiments of the disclosure relate to silica nanofiber materials, to articles comprising such materials, and to methods of forming such materials and articles.

### BACKGROUND

Power transformers are electrical devices that transfer electrical energy using electromagnetic induction. Typically, transformers include wound conductive wires covered with insulation to prevent shorting of adjacent wires. Transformers are used to increase or decrease the voltage of transmitted energy. Transformers are used in power distribution systems because power is typically transmitted over long distances at much higher voltage (e.g., 500,000 volts) than the voltage required by end users (e.g., 240 volts). Transformers may be used to increase the voltage of power transferred from a generating station to transmission lines, and to decrease the voltage of power transferred from transmission lines to substations and, ultimately, to end users.

Power transformers are vital components of the electrical grid, and are vulnerable to premature failure due to exposure to geomagnetic disturbances (GMD) and electromagnetic pulses associated with nuclear blasts. These events may, if in close enough proximity, induce higher-than-normal currents in transformers, which may cause elevated temperatures and voltages that compromise the insulation in the transformers. Failure of transformers can cause power outages. If due to a GMD, many transformers may be affected at the same time, straining repair crews, causing economic losses, and even loss of life.

Conventional insulation used in transformers and other electrical components may include organic polymers or micro-fibers embedded in a temperature-sensitive binding matrix selected for structural stability. Such materials may degrade at high temperatures. It would be beneficial to have an insulation material that is stable at temperatures commonly encountered in transformers during or after a GMD. Such insulation materials may also be beneficial for any other application where unusually high transformer temperatures might be expected.

### BRIEF SUMMARY

In some embodiments, a silica nanofiber material includes a flexible mat comprising a plurality of silica nanofibers. An electrical device may include an electrical component and the silica nanofiber material disposed over the electrical component.

A method of forming a silica nanofiber material includes electrospinning a fluid comprising a silica precursor and a polymer to form electrospun fibers, removing at least a portion of the polymer from the electrospun fibers to form silica nanofibers, and annealing the silica nanofibers to bind the silica nanofibers together.

### BRIEF DESCRIPTION OF THE DRAWINGS

FIG. 1 is a simplified top view of a silica nanofiber material in the form of a flexible, woven mat, according to embodiments of the disclosure.

FIG. 2 is a simplified view of a silica nanofiber thread, according to embodiments of the disclosure, which thread may be used in the flexible, woven mat of FIG. 1.

FIG. 3 is a simplified view illustrating a silica nanofiber of a silica nanofiber material, according to embodiments of the disclosure.

FIG. 4 is a simplified view illustrating a silica nanofiber material in the form of a flexible mat having multiple silica nanofibers, such as those shown in FIG. 3.

FIG. 5 is a simplified diagram showing an electrical device having an electrically insulating material comprising silica nanofibers, according to embodiments of the disclosure.

FIG. 6 is a simplified view of a portion of an electrical transformer having an electrically insulating material comprising silica nanofibers, according to embodiments of the disclosure.

FIG. 7 is a simplified view of a portion of a conductor wrapped with an insulating material comprising silica nanofibers, according to embodiments of the disclosure.

FIG. 8 is a simplified diagram showing an electrospinning process to form silica nanofibers or a silica nanofiber material comprising silica nanofibers, according to embodiments of the disclosure.

FIG. 9 shows a simplified cross section of a portion of an electrospun fiber comprising silica particles, according to embodiments of the disclosure.

FIG. 10 is a simplified diagram showing another electrospinning process to form silica nanofibers or a silica nanofiber material comprising silica nanofibers, according to embodiments of the disclosure.

FIG. 11 is a cross-sectional and elevational simplified diagram showing a pipe with an outer layer of a silica nanofiber material, according to embodiments of the disclosure.

FIG. 12 is a cross-sectional and elevational simplified diagram showing a pipe with an inner layer of a silica nanofiber material, according to embodiments of the disclosure.

FIG. 13 is a cross-sectional and elevational simplified diagram showing a pipe with both an outer layer and an inner layer of silica nanofiber material, according to embodiments of the disclosure.

FIG. 14 is a simplified top view of a silica nanofiber material in the form of a woven mat for use as a filter, according to embodiments of the disclosure.

### DETAILED DESCRIPTION

The illustrations presented herein are not actual views of any particular fiber, thread, material, mat, article, component, device, or system, but are merely idealized representations that are employed to describe example embodiments of the present disclosure. Additionally, elements common between figures may retain the same numerical designation.

The following description provides specific details, such as material types, dimensions, and processing conditions in order to provide a thorough description of embodiments of the disclosure. However, a person of ordinary skill in the art will understand that the embodiments of the disclosure may be practiced without employing these specific details. Indeed, the embodiments of the disclosure may be practiced in conjunction with conventional techniques employed in the industry. In addition, the description provided below does not form a complete process flow, apparatus, system, or method for forming fibers, threads, materials, or articles (e.g., components, devices (e.g., electrical devices)). Only those process acts and structures necessary to understand the embodiments of the disclosure are described in detail below. Additional acts may be performed by conventional techniques. Also note, the drawings accompanying the present application are for illustrative purposes only, and are thus not necessarily drawn to scale.

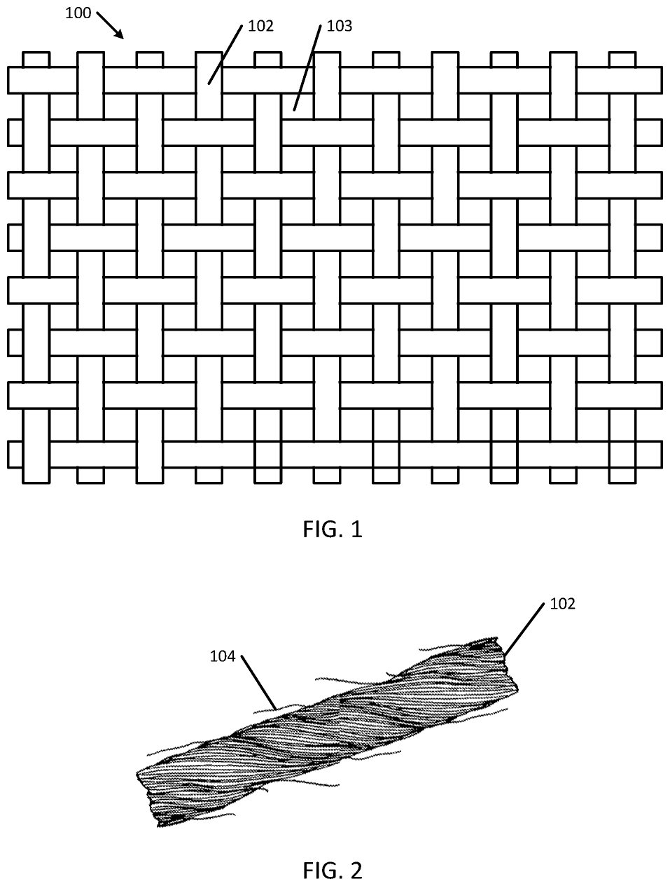

FIG. 1 is a simplified top view of a silica nanofiber material in the form of a flexible mat 100, which may be conducive for use as an electrically-insulating material, as a thermally-insulating material, as a corrosion-resistant material, and/or as a filter. The flexible mat 100 is formed of a plurality of threads 102. The threads 102 are shown in more detail in FIG. 2, and may include a plurality of silica nanofibers 104 wound, braided, or otherwise connected to be cohesive and flexible. As shown in FIG. 1, the threads 102 may be woven to form the flexible mat 100.

The silica nanofibers 104 may exhibit a mean diameter from about 100 nm to about 1,000 nm (1 μm) and a length from about 1 mm to about 100 mm. The threads 102, which may contain many thousands or millions of silica nanofibers 104, may exhibit a mean diameter from, for example, about 10 μm to about 500 μm. The threads 102 may have any selected length, and may be essentially continuous (e.g., long enough to be woven to form the flexible mat 100 shown in FIG. 1).

The flexible mat 100 may define spaces 103 between adjacent threads 102. FIG. 1 is not to scale, and the spaces 103 may have any selected dimension. For example, the spaces 103 may have a width approximately equal to the diameter of the threads 102, approximately half the diameter of the threads 102, etc. In some embodiments, other weave patterns may be used to decrease the size and/or number of the spaces 103. Though only one layer of woven threads 102 is shown in FIG. 1, the flexible mat 100 may include multiple layers of woven threads 102. Multiple layers may aid in preventing flow of gases through the flexible mat 100, and may thus increase the thermal insulative properties of the flexible mat 100.

In some embodiments, the silica nanofibers 104 may include a polymer coating thereon. For example, the silica nanofibers 104 may include a binder material such as polyvinyl alcohol (“PVA”), polyvinyl acetate (“PVAc”), polyethylene oxide (“PEO”), polyvinyl ether, polyvinyl pyrrolidone, polyglycolic acid, polyvinylidene difluoride (PVDF), hydroxyethylcellulose (“HEC”), ethylcellulose, cellulose ethers, polyacrylic acid, polyisocyanate, polyacrylonitrile (“PAN”), a polyacrylate, etc. The polymer coating, if present, may be a material used to form the silica nanofibers 104. In other embodiments, the silica nanofibers 104 may be substantially free of organic material.

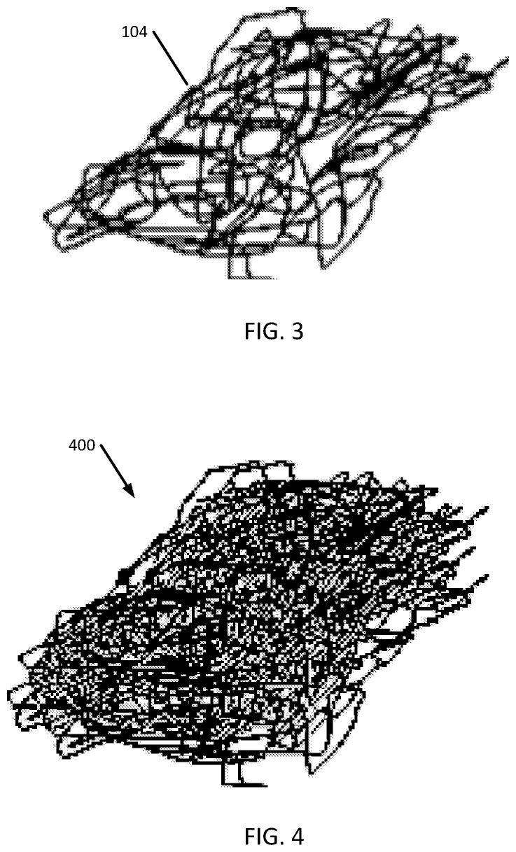

FIG. 3 is a simplified view illustrating another embodiment of a silica nanofiber 104 that may be used to form a silica nanofiber material (e.g., an electrically-insulating material, a thermally-insulating material, a corrosion-resistant material, a filtration material). As shown in FIG. 3, the silica nanofiber 104 may be entangled or arranged in a random orientation. In some embodiments, a single silica nanofiber 104 may be folded over on itself at one or more contact points. The silica nanofiber 104 may be chemically or physically bonded to itself at points where it contacts itself.

FIG. 4 is a simplified view illustrating a silica nanofiber material in the form of a flexible mat 400 having multiple silica nanofibers 104, such as those shown in FIG. 3, adjacent one another. The silica nanofibers 104 may be chemically or physically bonded to adjacent silica nanofibers 104 at points of contact. In some embodiments, silica nanofibers 104 may be pressed to cause them to mutually adhere together, for example in a felting process, wherein the silica nanofibers 104 may be matted, condensed and pressed together. In the flexible mats 100, 400 shown in FIGS. 1 and 4, the silica nanofibers 104 may be interlocked together, such that the silica nanofibers 104 are generally captive when the flexible mat 100, 400 is moved or flexed. That is, the flexible mat 100, 400 may be flexed back and forth in a bending or folding action without breaking the flexible mat 100, 400.

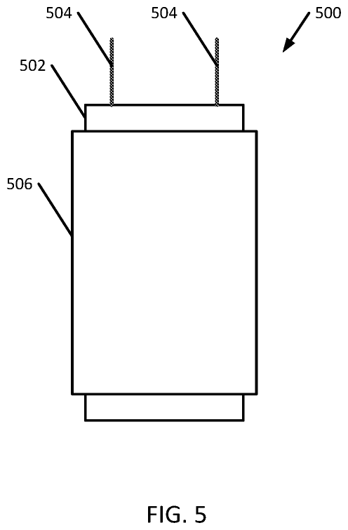

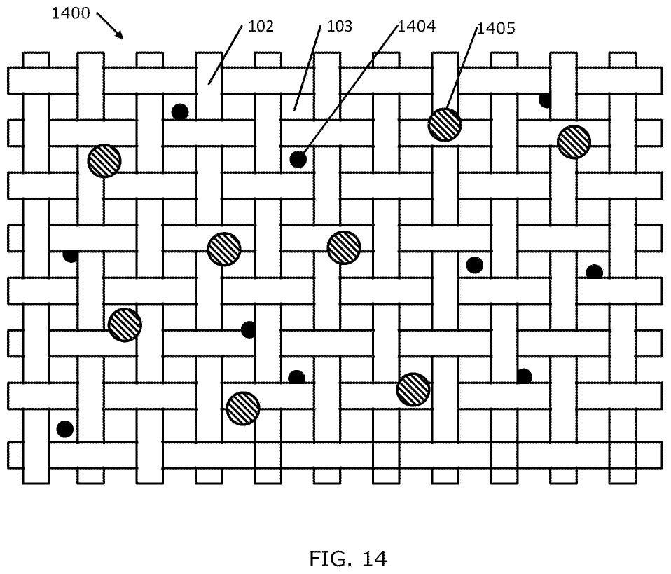

The flexible mat 100, 400 may have similar physical properties to a sheet of paper or fabric, and may therefore be used as a replacement for conventional paper or woven insulation materials. In other embodiments, the flexible mat 100, 400 may be used as a thermal-insulation material (e.g., as a protective layer on an article to be used in high- or low-temperature environments (as discussed further, below, with regard to FIGS. 5, 11, and 13), as a corrosion-resistant materials (e.g., as a protective layer on an article to be used around corrosive chemicals or conditions (as discussed further, below, with regard to FIGS. 12 and 13), and/or as a filter (as discussed further, below, with regard to FIG. 14).

In some embodiments, flexible mat 100, 400 may include an inorganic binder adjacent to and connecting the silica nanofibers 104. For example, the inorganic binder, if present, may include another ceramic material, a metal oxide, or any combination thereof. The inorganic binder may be selected for high thermal stability and low electrical and thermal conductivity.

FIG. 5 is a simplified diagram showing an article (e.g., an electrical device 500) having an electrically insulating material, such as the silica nanofiber material of the flexible mat 100, 400 as shown in FIGS. 1 and 4. The electrical device 500 may include an electrical component 502 having an electrically insulating material 506 (e.g., silica nanofiber material) over at least some surfaces of the electrical component 502. For example, the electrically insulating material 506 may be one of the flexible mats 100, 400 shown in FIGS. 1 and 4. The electrically insulating material 506 may be wound or layered around the electrical component 502 or portions thereof to provide a selected amount of electrical and/or thermal insulation to the electrical component 502. Thus, the electrically insulating material 506 may also be configured as a thermal-insulation material.

In some embodiments, the electrical component 502 may include an integrated circuit or a portion thereof, e.g., a transistor, a diode, a capacitor, a resistor, an op-amp, etc. The electrical component 502 may have one or more electrical connectors 504 (e.g., wires, electrodes, etc.) to connect the electrical component 502 to other systems or devices.

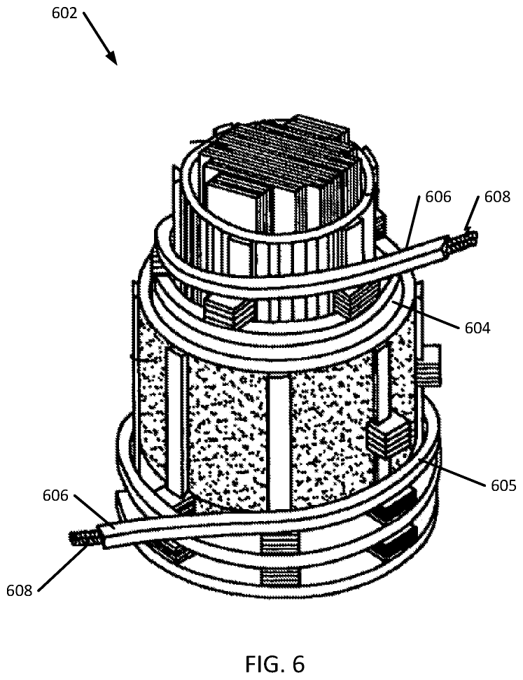

FIG. 6 is a simplified view of a portion of another article, namely, an electrical transformer 602 including an electrically insulating material. The transformer 602 may be used in an oil-filled power system. The transformer 602 may include a low voltage winding coil 604 and a high voltage winding coil 605. The coils 604, 605 may include wires 608 having an electrically insulating material 606 around the wires 608. The electrically insulating material 606 may be any of the silica nanofiber material described herein.

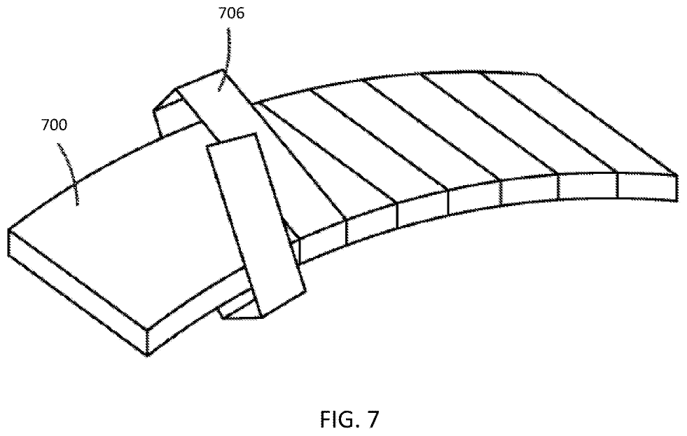

FIG. 7 is a simplified view of a portion of another article, namely, a conductor 700, wrapped with an insulating material 706. The insulating material 706 may comprise silica nanofibers in the form of either of the flexible mats 100, 400 shown in FIGS. 1 and 4. The conductor 700 may be used to form a coil (e.g., elements 604 and 605 as shown in FIG. 6), and the insulating material 706 may electrically isolate the conductor 700 from other conductors. Thus, the insulating material 706 may be used as element 606 in FIG. 6. If the conductor 700 is coiled into loops, the insulating material 706 may prevent physical contact between adjacent loops of the conductor 700. The conductor 700 may have any selected cross-sectional shape. As shown, the conductor 700 has a rectangular cross section, but other shapes, such as circular, triangular, etc., may also be used.

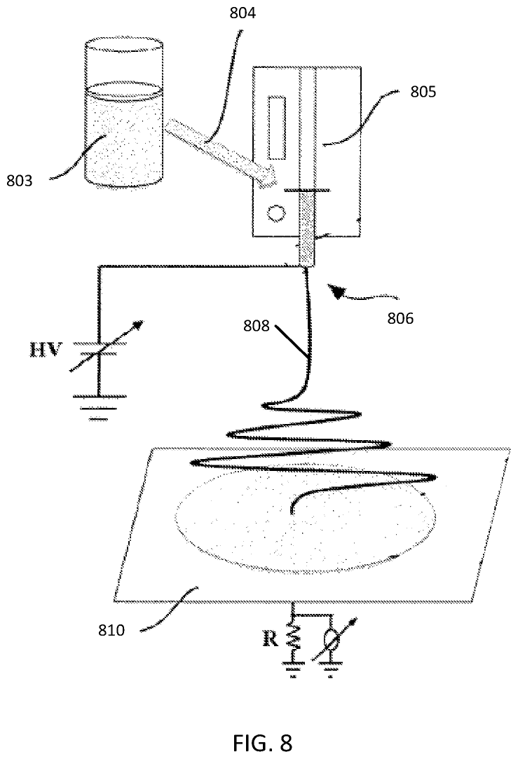

Silica nanofiber materials, such as the flexible mats 100, 400 shown in FIGS. 1 and 4, may be formed using an electrospinning process. For example, a fluid 804 (FIG. 8) comprising a silica precursor may be prepared (e.g., in a holding tank 803), such as by mixing a silicon-containing material with a polymer. The silicon-containing material may include, for example, silicon oxide, alkoxide, halide, or acetate. In some embodiments, the silicon-containing material may include elemental silicon. The polymer may include, for example, polyvinyl alcohol, polyvinyl acetate, polyethylene oxide, polyvinyl ether, polyvinyl pyrrolidone, polyglycolic acid, polyvinylidene difluoride, polyacrylonitrile, polyacrylic acid, polymethylmethacrylate, or a combination thereof. In some embodiments, the fluid may also include water, alcohol, a hydrocarbon solvent, DMF, or a combination thereof, or any other selected solvent or combination of solvents.

As shown in FIG. 8, the fluid 804 may be transferred from the holding tank 803 to an electrospinning apparatus 805 having a needle 806. The fluid 804 may be provided to the electrospinning apparatus 805 by any device, such as a syringe or a pump. The fluid 804 may be passed through the needle 806 while an electric potential (i.e., a voltage) is applied to the needle 806. The electric potential may be sufficient to overcome the surface tension of the fluid 804 to produce a stream of the fluid 804 emanating from needle 806, which forms an electrospun fiber 808. In some embodiments, a gas may be provided to the electrospinning apparatus 805 (e.g., by an air pump) to promote the flow of the fluid 804 leaving the needle 806.

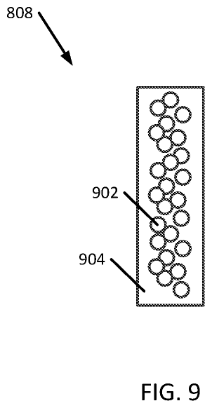

FIG. 9 shows a simplified cross section of a portion of the electrospun fiber 808, e.g., an electrospun silicon nanofiber. The electrospun fiber 808 may have particles 902 (e.g., silica particles) suspended in or surrounded by polymer 904. Referring again to FIG. 8, the fluid 804 may travel generally toward a grounded collector 810. The electric potential applied to the solution (e.g., the fluid 804) prevents the stream from breaking up into small droplets, but allows the fluid 804 to hold together while elongating towards the collector 810. As the solvent evaporates from the fluid 804, monomers (i.e., of the polymer) within the fluid 804 polymerize into the fiber 808, which is then collected by the collector 810. The electrospun fiber 808 may be flexible, and therefore the electrospun fiber 808 may become entangled on the collector 810. The electrospun fiber 808 may be in a form similar to the silica nanofiber 104 shown in FIG. 3.

In some embodiments, the collector 810 may be a surface of an article on which the silica nanofiber material is to be formed. Thus, a silica nanofiber material, e.g., in the form of the flexible mat 400 of FIG. 4, may be formed directly on the article it will insulate or otherwise protect. In other embodiments, the silica nanofiber material may be separately formed and then applied (e.g., attached, adhered, connected) to the article it is to insulate or otherwise protect.

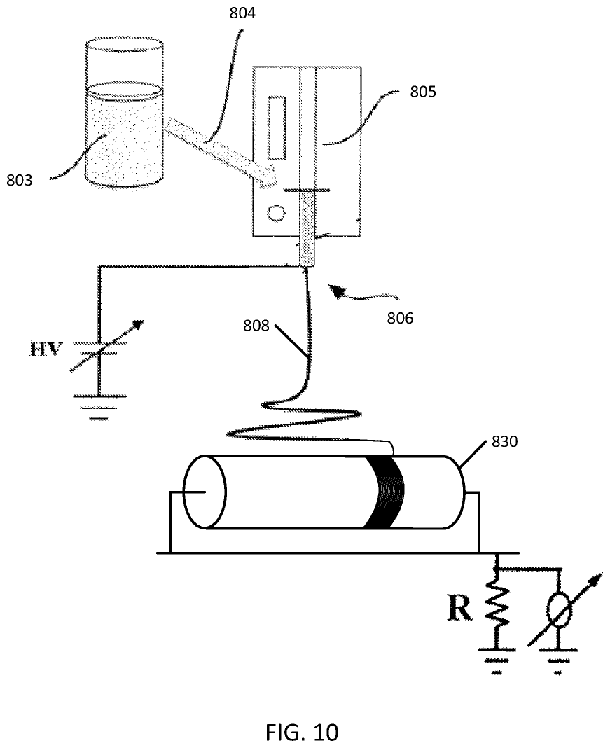

In some embodiments, and as shown in FIG. 10, the electrospun fiber 808 may be collected on a rotating collector 830. The electrospun fiber 808 may be spooled to form a continuous thread (e.g., thread 102 of FIG. 2). The rotating collector 830 may be electrically grounded. In some embodiments, the electrospun fiber 808 (e.g., the thread 102) may then be used (e.g., in thread form or after further fabrication into a yarn) to form a silica nanofiber material, e.g., in the form of the flexible mat 100 of FIG. 1, with its woven structure, or in the form of the flexible mat 400 of FIG. 4, with its more entangled thread arrangement. Thus, the system of FIG. 10 may be used to first form the silica nanofiber in the form of an electrospun fiber 808 before the electrospun fiber 808 is used form a silica nanofiber material (e.g., in the form of the flexible mat 100 (FIG. 1) or 400 (FIG. 4)), before the silica nanofiber material is applied (e.g., attached, adhered, connected) to the article it is to insulate or otherwise protect. In other embodiments, however, the electrospun fiber 808 may be formed directly on the article it is to protect. That is, the rotating collector 830 may be a surface of an article on which the silica nanofiber material is to be formed, and the electrospun fiber 808 (e.g., a silica nanofiber) may be formed directly on the article, forming an insulative or otherwise-protective layer of silica nanofiber material in the form of a wound coil.

Returning again to FIG. 9, the particles 902 in the electrospun fiber 808 may be held together by the polymer 904, but may nonetheless be separable from one another under certain conditions (e.g., mixture with a solvent in which the polymer 904 is soluble). To form the particles 902 into a more cohesive fiber, the polymer 904 or a portion thereof may be removed from the electrospun fiber 808, leaving the particles 902 in the electrospun fiber 808. For example, the electrospun fiber 808 may be heated to a temperature at which the polymer begins to decompose, evaporate, or otherwise change form. The particles 902 or portions thereof may melt and fuse together to form the electrospun fiber 808 into a continuous strand (e.g., a continuous silica nanofiber) that has a structure separate from the polymer 904. In some embodiments, this may occur simultaneously with the removal of the polymer 904. In other embodiments, the electrospun fiber 808 may be subjected to a separate annealing process to coalesce into an electrospun fiber substantially free of polymer 904. Thus, the resulting silica nanofiber may be substantially free of polymer 904.

In some embodiments, the polymer 904 may be removed from the electrospun fiber 808 after forming the shape of the final silica nanomaterial (e.g., prior to forming the thread 102 of FIG. 2 from the electrospun fiber 808, prior to weaving the threads 102 into the flexible mat 100 of FIG. 1, prior to forming the flexible mat 400 of FIG. 4). In other embodiments, the polymer 904 may be removed from the electrospun fiber 808 before forming the shape of the final silica nanomaterial or after forming the thread 102 (FIG. 2), 104 (FIG. 3) but before using the thread 102, 104 to form the shape of the final silica nanomaterial.

Returning again to FIG. 3, the silica nanofiber 104 may be exposed to a suspension of silica nanoparticles in a solvent (e.g., water, an alcohol, etc.). For example, the silica nanofiber 104 may be sprayed with the suspension, dipped in a bath containing the suspension, etc. The silica nanofiber 104 may be heated to remove the solvent, leaving silica nanoparticles on the silica nanofiber 104. Heating may also cause the silica nanoparticles to melt and fuse to the silica nanofiber 104, and may link parts of the silica nanofiber 104 together. Such a process may be performed on multiple silica nanofibers 104 to link them to one another and form the flexible mat 400 shown in FIG. 4.

In some embodiments, silica nanofibers 104 may be used to form the threads 102 shown in FIG. 2. For example, the silica nanofibers 104 may be wound, braided, or otherwise connected by any method known in the art. The threads 102 may then be woven to form the flexible mat 100 shown in FIG. 1. In other embodiments, silica particles may be attached to the silica nanofibers, simulating ridges on wool fibers and allowing felting of the nanofibers to produce a binder-free silica felt. In further embodiments, the silica nanofibers 104 may be fabricated into yarns, or woven into a silica fabric comprising the silica nanofibers 104 or yarns of the silica nanofibers 104.

In some embodiments, the flexible mats 100, 400 shown in FIGS. 1 and 4 may be subjected to a volume-reduction process to reduce the volume of free space between the silica nanofibers 104. In some embodiments, the flexible mats 100, 400 may be wetted with a solvent, such as water, an alcohol, a hydrocarbon, etc. The solvent may then be evaporated from the flexible mats 100, 400. Capillary action may draw the silica nanofibers 104 together as the solvent evaporates. In some embodiments, the solvent may include an additive to enhance wetting of the silica nanofibers 104. For example, the additive may include sulfates, phosphates, Zwitterionic molecules, silicones, alkoxylates, polymers, and sulfosuccinates.

In some embodiments, an inorganic binder may be added to the flexible mat 100, 400 to improve connection between the silica nanofibers 104. For example, another ceramic material, a metal oxide, or any combination thereof, may be added to the flexible mats 100, 400 with a solvent (e.g., during the solvent-wetting process described above). At least a portion of the inorganic binder may remain on the silica nanofibers 104 when the solvent is removed.

The flexible mats 100, 400 illustrated and described herein may be beneficial for use as electrical insulation materials in various electrical devices because they may have physical properties comparable to paper and dielectric properties comparable to glass. Thus, the flexible mats 100, 400 may be more durable than glass insulators and exhibit superior dielectric properties to paper insulators. For example, the flexible mats 100, 400 may be thermally stable at temperatures of at least 400° C. or even at least 450° C., over a period of 700 hours. In some embodiments, such as those in which the silica nanofiber material does not include a binder, the flexible mats 100, 400 may be thermally stable at temperatures even up to 1200° C. The flexible mats 100, 400 may survive 35,000 fold endurance cycles or more without breaking. The flexible mats 100, 400 may have a breakdown voltage of 20 MV/m or more, and an electrical resistivity of 10¹⁵ Ohm·m or more. The flexible mats 100, 400 may be stacked or wound to any selected thickness, as desired for a particular application.

The flexible mats 100, 400 may be particularly useful in electrical transformers. However, the flexible mats 100, 400 may be used in any other electrical devices. For example, the flexible mats 100, 400 may be used to insulate electronics for aerospace vehicles, satellites, seacraft, land vehicles, solar cells, communication equipment, etc. Because the flexible mats 100, 400 may provide superior electrical insulation to conventional insulation materials, the electrical devices in which the flexible mats 100, 400 are used may be made smaller than conventional devices. In particular, the flexible mats 100, 400 having improved thermal tolerances may enable devices to operate at higher temperatures without damage. Thus, the flexible mats 100, 400 may provide both electrical insulation and thermal insulation. All other factors being equal, devices that are smaller but consume the same amount of power will operate at higher temperatures. Therefore, the use of insulation materials (e.g., the flexible mats 100, 400) that can withstand higher temperatures may enable a device to be made smaller. Smaller devices may lead to cost savings, space savings, weight savings, etc.

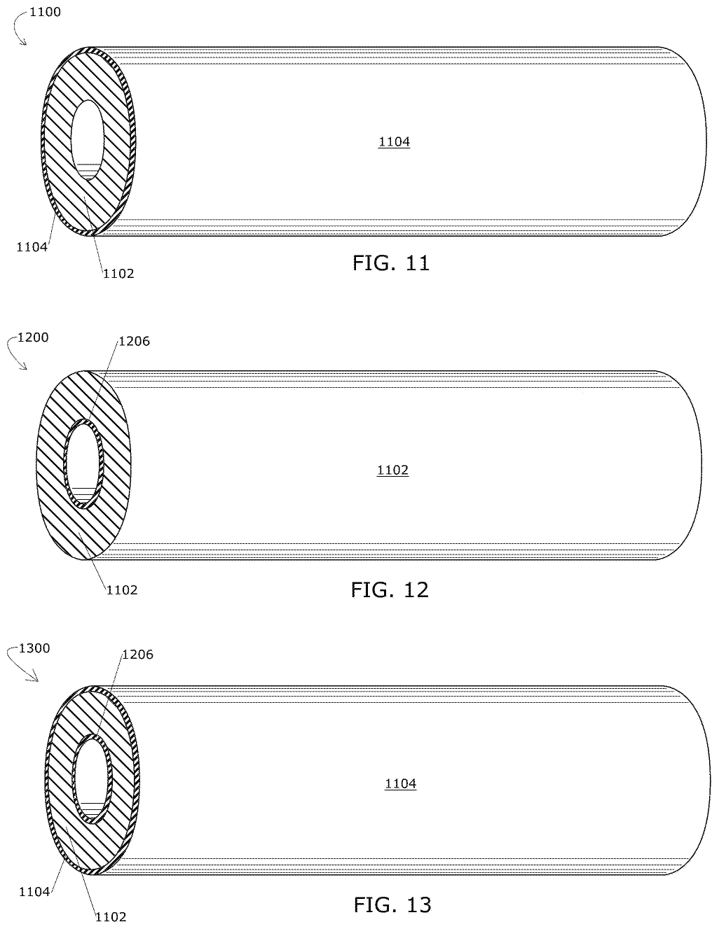

In some embodiments, the silica nanofiber material may be configured for use as a thermally-insulative material for an article, whether the silica nanofiber material may or may not also provide electrical insulation to the article. For example, with reference to FIG. 11, a thermally-insulated pipe 1100 may be formed by providing—around an exterior surface of a pipe 1102—a silica nanofiber material 1104, which may be in the form of the flexible mat 100 of FIG. 1 (e.g., a woven mat), in the form of the flexible mat 400 of FIG. 4 (e.g., a felted mat), or in the form of a wound coil (see, FIG. 10). As discussed above, such a silica nanofiber material 1104 may be formed directly on the surface of the pipe 1102 or may be formed separately, first, and then applied to the surface of the pipe 1102.

While FIG. 11 illustrates the thermally-insulative material of the silica nanofiber material 1104 as being on only an exterior surface of the thermally-insulated pipe 1100, in other embodiments, the silica nanofiber material 1140 may be, alternatively or additionally, included on another surface (e.g., an interior surface) of the thermally-insulated pipe 1100 and/or along select portions of the surface of the thermally-insulated pipe 1100. Likewise, the use of the silica nanofiber material 1104 as a thermally-insulative material is not limited to articles in the form of pipes, but may also include other types of articles (e.g., components, devices).

In some embodiments, the silica nanofiber material may be configured for use as a protectant material, such as a corrosion-resistant, a wear-resistant material, or both. For example, with reference to FIG. 12, a corrosion-resistant pipe 1200 may include a layer of silica nanofiber material 1206 along an interior wall of the pipe 1102. The presence of the silica nanofiber material 1206—which may be in the form of the flexible mat 100 of FIG. 1 (e.g., a woven mat), in the form of the flexible mat 400 of FIG. 4 (e.g., a felted mat), or in the form of a wound coil of FIG. 10—may prevent or inhibit contact between the covered material (e.g., the material of interior wall of the pipe 1102) and a corrosive or otherwise-potentially-damaging material passing through the pipe 1102. For example, the corrosion-resistant pipe 1200 may be used to pass a material (e.g., a very hot material (e.g., molten salt), a very cold material (e.g., liquid nitrogen), a wear-causing material (e.g., a pressurized particle stream), an otherwise corrosive material (e.g., an acid)), and the presence of the silica nanofiber material 1206 may tolerate the passage of the material without damage to the silica nanofiber material 1206 or to the underlying material of the pipe 1102. As discussed above, such a silica nanofiber material as the silica nanofiber material 1206 may be formed directly on the surface (e.g., the interior surface, according to FIG. 12) of the pipe 1102 or may be formed separately, first, and then applied to the surface (e.g., the interior surface) of the pipe 1102.

While FIG. 12 illustrates the corrosion-resistant or wear-resistant material of the silica nanofiber material 1206 as being on only an interior surface of the corrosion-resistant pipe 1200, in other embodiments, the silica nanofiber material 1206 may be, alternatively or additionally, included on another surface (e.g., an exterior surface) of the corrosion-resistant pipe 1200 and/or along select portions of the surface of the corrosion-resistant pipe 1200. Likewise, the use of the silica nanofiber material 1206 as a corrosion-resistant (e.g., wear resistant material) is not limited to articles in the form of pipes, but may also include other types of articles (e.g., components, devices).

In some embodiments, multiple surfaces of an article may include protection in the form of silica nanofiber material, whether for electrical insulation, thermal insulation, corrosion resistance (e.g., wear resistance), or a combination thereof. For example, with respect to FIG. 13, a dual-protected pipe 1300 may include the silica nanofiber material 1104 of FIG. 11 as well as the silica nanofiber material 1206 of FIG. 12. The silica nanofiber material 1104 may provide thermal insulation along the exterior of the pipe 1102, such as if hot materials are passing through the pipe 1102, making the dual-protected pipe 1300 safer for possible human contact. The silica nanofiber material 1104 may also provide corrosion resistance, such as preventing contact between a condensate and the surface of the pipe 1102, which condensate may otherwise cause damage to the material of the pipe 1102. Meanwhile, the silica nanofiber material 1206 on the interior of the dual-protected pipe 1300 may provide corrosion resistance from the material passing through the dual-protected pipe 1300.

In other embodiments, the silica nanofiber material—which may be in the form of the flexible mat 100 of FIG. 1 (e.g., a woven mat), in the form of the flexible mat 400 of FIG. 4 (e.g., a felted mat), or in the form of a wound coil of FIG. 10—may be configured to provide protection to an underlying material (e.g., of an article, of a person) from other potentially-damaging exposures, such as flames or electric arcs.

In some embodiments, the silica nanofiber material may be configured as a filtration material (e.g., as a filter). For example, and with reference to FIG. 14, the silica nanofiber material may be in the form of a woven filter 1400, which may be formed in the same manner as the flexible mat 100 of FIG. 1, with the dimensions of the spaces 103 of the weave tailored to be permeable to targeted nanomaterials 1404 without being permeable to other nanomaterials 1405. Thus, the woven filter 1400 may be used to separate the targeted nanomaterials 1404 from the other nanomaterials 1405. In other embodiments, such a filter may be in the form of the flexible mat 400 of FIG. 4, with spaces in mat being tailored to be permeable to the targeted nanomaterials 1404 without being permeable to the other nanomaterials 1405. Thus, the silica nanofiber material, as disclosed, may be configured for use as a filter (e.g., a particulate filter, a filter of a water-filtration system, a filter in a refinery process, a filter in another industrial process). Because the silica nanofiber material is tolerable of harsh conditions (e.g., high temperatures, low temperatures, otherwise-corrosive environments), the silica nanofiber material enables forming a filter for use in harsh conditions.

Additional non limiting example embodiments of the disclosure are described below.

### Embodiment 1

A silica nanofiber material comprising a flexible mat comprising a plurality of silica nanofibers.

### Embodiment 2

The silica nanofiber material of Embodiment 1, wherein the flexible mat comprises the plurality of silica nanofibers in a form of felted silica nanofibers.

### Embodiment 3

The silica nanofiber material of Embodiment 1 or Embodiment 2, wherein the silica nanofibers are interlocked together.

### Embodiment 4

The silica nanofiber material of any one of Embodiments 1 through 3, wherein the silica nanofibers exhibit mean diameters from about 100 nm to about 1,000 nm.

### Embodiment 5

The silica nanofiber material of any one of Embodiments 1 through 4, wherein the flexible mat comprises a plurality of woven threads, each thread comprising multiple silica nanofibers of the plurality of silica nanofibers.

### Embodiment 6

The silica nanofiber material of any one of Embodiments 1 through 5, wherein the silica nanofibers comprise a polymer coating.

### Embodiment 7

The silica nanofiber material of any one of Embodiments 1 through 6, further comprising an inorganic binder adjacent to and connecting the silica nanofibers.

### Embodiment 8

An electrical device comprising an electrical component, and the silica nanofiber material of any one of Embodiments 1 through 7 disposed on at least one surface of the electrical component.

### Embodiment 9

The electrical device of Embodiment 8, wherein the electrical component comprises a transformer having a coiled electrical conductor comprising a plurality of loops, and wherein the silica nanofiber material is disposed over the electrical conductor of the coil and prevents physical contact between adjacent loops of the electrical conductor.

### Embodiment 10

The electrical device of Embodiment 8 or Embodiment 9, wherein the silica nanofiber material comprises a layered material over the electrical component.

### Embodiment 11

The electrical device of any one of Embodiments 8 through 10, wherein the silica nanofiber material is wound around the electrical component.

### Embodiment 12

The electrical device of any one of Embodiments 8 through 11, wherein the electrical component comprises an integrated circuit.

### Embodiment 13

A method of forming a silica nanofiber material, the method comprising electrospinning a fluid comprising a silica precursor and a polymer to form electrospun fibers, removing at least a portion of the polymer from the electrospun fibers to form silica nanofibers, and annealing the silica nanofibers to bind the silica nanofibers together.

### Embodiment 14

The method of Embodiment 13, further comprising exposing the silica nanofibers to a suspension comprising silica nanoparticles.

### Embodiment 15

The method of Embodiment 14, wherein annealing the silica nanofibers comprises binding the silica nanoparticles of the suspension to the silica nanofibers.

### Embodiment 16

The method of any one of Embodiments 13 through 15, wherein removing at least a portion of the polymer from the electrospun fibers comprises heating the electrospun fibers to decompose the polymer.

### Embodiment 17

The method of any one of Embodiments 13 through 16, further comprising forming threads from a plurality of the silica nanofibers.

### Embodiment 18

The method of Embodiment 17, further comprising weaving the threads to form a woven flexible mat.

### Embodiment 19

The method of any one of Embodiments 13 through 18, further comprising reducing a volume of free space between the silica nanofibers.

### Embodiment 20

The method of Embodiment 19, wherein reducing a volume of free space between the silica nanofibers comprises wetting the silica nanofibers with a solvent and evaporating the solvent from the silica nanofibers.

### Embodiment 21

The method of Embodiment 20, wherein wetting the silica nanofibers with a solvent comprises wetting the silica nanofibers with water.

While the present disclosure has been described herein with respect to certain illustrated embodiments, those of ordinary skill in the art will recognize and appreciate that it is not so limited. Rather, many additions, deletions, and modifications to the illustrated embodiments may be made without departing from the scope of the disclosure as hereinafter claimed, including legal equivalents thereof. In addition, features from one embodiment may be combined with features of another embodiment while still being encompassed within the scope of the disclosure as contemplated. Further, embodiments of the disclosure have utility with different and various devices and materials.

What is claimed is:

1. A silica nanofiber material comprising:
a flexible mat comprising a plurality of silica nanofibers.

2. The silica nanofiber material of claim 1, wherein the flexible mat comprises the plurality of silica nanofibers in a form of felted silica nanofibers.

3. The silica nanofiber material of claim 1, wherein the silica nanofibers are interlocked together.

4. The silica nanofiber material of claim 1, wherein the silica nanofibers exhibit mean diameters from about 100 nm to about 1,000 nm.

5. The silica nanofiber material of claim 1, wherein the flexible mat comprises a plurality of woven threads, each thread comprising multiple silica nanofibers of the plurality of silica nanofibers.

6. The silica nanofiber material of claim 1, wherein the silica nanofibers comprise a polymer coating.

7. The silica nanofiber material of claim 1, further comprising an inorganic binder adjacent to and connecting the silica nanofibers.

8. An electrical device comprising:
an electrical component;
the silica nanofiber material of claim 1 disposed on at least one surface of the electrical component.

9. The electrical device of claim 8, wherein the electrical component comprises a transformer having a coiled electrical conductor comprising a plurality of loops, and wherein the silica nanofiber material is disposed over the electrical conductor of the coil and prevents physical contact between adjacent loops of the electrical conductor.

10. The electrical device of claim 8, wherein the silica nanofiber material comprises a layered material over the electrical component.

11. The electrical device of claim 8, wherein the silica nanofiber material is wound around the electrical component.

12. The electrical device of claim 8, wherein the electrical component comprises an integrated circuit.

13. A method of forming a silica nanofiber material, the method comprising:
electrospinning a fluid comprising a silica precursor and a polymer to form electrospun fibers;
removing at least a portion of the polymer from the electrospun fibers to form silica nanofibers; and
annealing the silica nanofibers to bind the silica nanofibers together.

14. The method of claim 13, further comprising exposing the silica nanofibers to a suspension comprising silica nanoparticles.

15. The method of claim 14, wherein annealing the silica nanofibers comprises binding the silica nanoparticles of the suspension to the silica nanofibers.

16. The method of claim 13, wherein removing at least a portion of the polymer from the electrospun fibers comprises heating the electrospun fibers to decompose the polymer.

17. The method of claim 13, further comprising forming threads from a plurality of the silica nanofibers.

18. The method of claim 17, further comprising weaving the threads to form a woven flexible mat.

19. The method of claim 13, further comprising reducing a volume of free space between the silica nanofibers.

20. The method of claim 19, wherein reducing a volume of free space between the silica nanofibers comprises:
wetting the silica nanofibers with a solvent; and
evaporating the solvent from the silica nanofibers.

21. The method of claim 20, wherein wetting the silica nanofibers with a solvent comprises wetting the silica nanofibers with water.
